(19) United States
(12) Patent Application Publication
(10) Pub. No.: US 2016/0072035 A1
(43) Pub. Date: Mar. 10, 2016

(54) THERMOELECTRIC GENERATOR

(71) Applicants: Yojiro IRIYAMA, Toyota-shi (JP); Takumi KAMINAGA, Toyota-shi (JP)

(72) Inventors: Yojiro IRIYAMA, Toyota-shi (JP); Takumi KAMINAGA, Toyota-shi (JP)

(73) Assignee: TOYOTA JIDOSHA KABUSHIKI KAISHA, Toyota-shi, Aichi-ken (JP)

(21) Appl. No.: 14/785,154

(22) PCT Filed: Apr. 16, 2014
(86) PCT No.: PCT/IB2014/000552

§ 371 Date: Oct. 16, 2015

(30) Foreign Application Priority Data
Apr. 16, 2013 (JP) 2013-085443

(51) Int. Cl. H01L 35/32

(52) U.S. Cl. CPC H01L 35/32

(57) ABSTRACT

A thermoelectric generator includes a structure, thermoelectric devices, a hollow port member, electric wires, a shielding member, and a cooling unit. The structure defines an enclosed space between a high-temperature medium and a low-temperature medium, and the enclosed space is in a low-oxygen condition. The thermoelectric devices are placed in the enclosed space. The port member has one end portion to which the structure is connected so that the port member communicates with the enclosed space, and the port member has an opening in the other end portion thereof. The electric wires are inserted through the port member, and each wire has one end portion connected to the thermoelectric devices, and the other end portion pulled out to the outside of the port member through the opening. The shielding member is fitted in the port member, and the electric wires pass through the shielding member. The cooling unit is configured to cool the shielding member.

### BACKGROUND OF THE INVENTION

1. Field of the Invention

The invention relates to a thermoelectric generator.

2. Description of Related Art

A thermoelectric conversion module is known in which thermoelectric semiconductors as thermoelectric devices are placed between a hot plate and a cold plate, and a container that covers the whole of thermoelectric semiconductors is provided so as to form an enclosed space within which the thermoelectric semiconductors are sealed (see, for example, Japanese Patent Application Publication No. 2006-049872 (JP 2006-049872 A)).

The container of the thermoelectric conversion module has a conducting portion for taking out electric power generated by the thermoelectric semiconductors, to the outside of the container. The conducting portion passes through a given location of the container, via an electric insulator as a shielding member that also serves as a sealing member. The electric insulator plays a role in maintaining airtightness of the container.

### SUMMARY OF THE INVENTION

However, in the case where the thermoelectric conversion module as described in JP 2006-049872 A is installed on an automobile, and exhaust gas of an internal combustion engine as a high-temperature medium is used as a high-temperature heat source, while coolant of the internal combustion engine as a low-temperature medium is used as a low-temperature heat source, the electric insulator may deteriorate under an influence of high-temperature exhaust gas, and the airtightness of the container may not be maintained. Therefore, the thermoelectric semiconductors (thermoelectric devices) may be exposed to a high-temperature atmosphere, and may be oxidized at high temperatures.

The invention provides a thermoelectric generator that is less likely to suffer from deterioration of a shielding member due to exhaust gas, and can prevent high-temperature oxidation of thermoelectric devices.

A thermoelectric generator according to one aspect of the invention includes a structure, a thermoelectric device, a hollow port member, an electric wire, a shielding member, and a cooling unit. The structure defines an enclosed space between a high-temperature medium and a low-temperature medium, and the enclosed space is in a low-oxygen condition. The thermoelectric device is placed in the enclosed space. The hollow port member has one end portion to which the structure is connected so that the port member communicates with the enclosed space, and the port member has an opening in the other end portion thereof. The electric wire is inserted through the port member, and the electric wire has one end portion connected to the thermoelectric device, and the other end portion that is pulled out to an outside of the port member through the opening. The shielding member is fitted in the port member, and the electric wire passes through the shielding member. The cooling unit is configured to cool the shielding member.

With the above arrangement, the thermoelectric generator is less likely to suffer from deterioration of the shielding member caused by the high-temperature medium, since the cooling unit cools the shielding member. Accordingly, the thermoelectric device is not exposed to the high-temperature atmosphere, and high-temperature oxidation of the thermoelectric device can be prevented.

In the thermoelectric generator as described above, the shielding member may be configured to seal the enclosed space and the port member to the outside.

In the thermoelectric generator as described above, the port member may extend outward from the structure, and the shielding member may be fitted in the opening of the port member.

With the above arrangement, the thermoelectric generator is less likely to suffer from deterioration of the shielding member caused by the high-temperature medium, since the shielding member is spaced apart from the high-temperature medium, and the quantity of heat received by the shielding member is reduced. Accordingly, the thermoelectric device is not exposed to the high-temperature atmosphere, and high-temperature oxidation of the thermoelectric device can be effectively prevented.

In the thermoelectric generator as described above, the cooling unit may comprise a radiating fin, and the radiating fin may be provided on an outer portion of the port member. Specifically, the radiating fin may be provided at a position close to or overlapping with the shielding member in an axial direction of the port member.

With the above arrangement, the thermoelectric generator is less likely to suffer from deterioration of the shielding member caused by the high-temperature medium, since the radiating fin releases heat received from the high-temperature medium so as to cool the shielding member. Accordingly, the thermoelectric device is not exposed to the high-temperature atmosphere, and high-temperature oxidation of the thermoelectric device can be effectively prevented.

In the thermoelectric generator as described above, the structure may have a low-temperature medium flow passage, and the shielding member may be located close to the low-temperature medium flow passage.

With the above arrangement, the thermoelectric generator is less likely to suffer from deterioration of the shielding member caused by the high-temperature medium, since the low-temperature medium flowing through the low-temperature medium flow passage cools the shielding member. Accordingly, the thermoelectric device is not exposed to the high-temperature atmosphere, and high-temperature oxidation of the thermoelectric device can be effectively prevented.

In the thermoelectric generator as described above, a pressure in the enclosed space may be reduced. Specifically, the pressure in the enclosed space may be below atmospheric pressure.

With the above arrangement, the pressure in the enclosed space is reduced, so that the enclosed space is kept in the low-oxygen condition; therefore, the thermoelectric generator can effectively prevent high-temperature oxidation of the thermoelectric device.

In the thermoelectric generator as described above, the enclosed space may be filled with inert gas.

With the above arrangement, the enclosed space is filled with the inert gas, so that the enclosed space is kept in the low-oxygen condition; therefore, the thermoelectric generator can effectively prevent high-temperature oxidation of the thermoelectric device.

According to this invention, the thermoelectric generator is less likely to suffer from deterioration of the shielding member caused by exhaust gas, and can prevent high-temperature oxidation of the thermoelectric device.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a vertical cross-sectional view schematically showing a thermoelectric generator according to one embodiment of the invention;

FIG. 2 is a transverse cross-sectional view of the thermoelectric generator according to the embodiment of the invention; and

FIG. 3 is a cross-sectional view taken along line in the thermoelectric generator shown in FIG. 1.

### DETAILED DESCRIPTION OF EMBODIMENTS

A thermoelectric generator according to one embodiment of the invention Will be described with reference to the drawings.

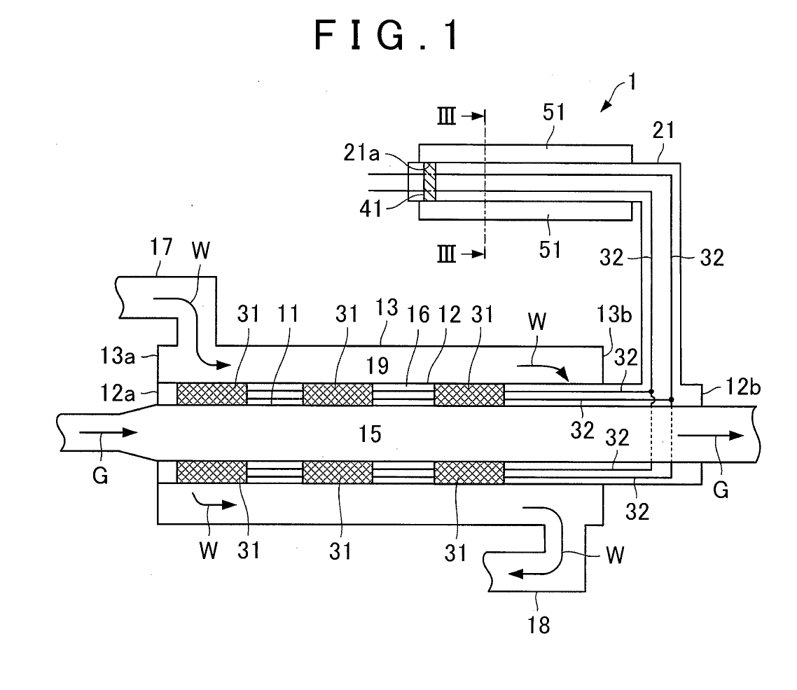

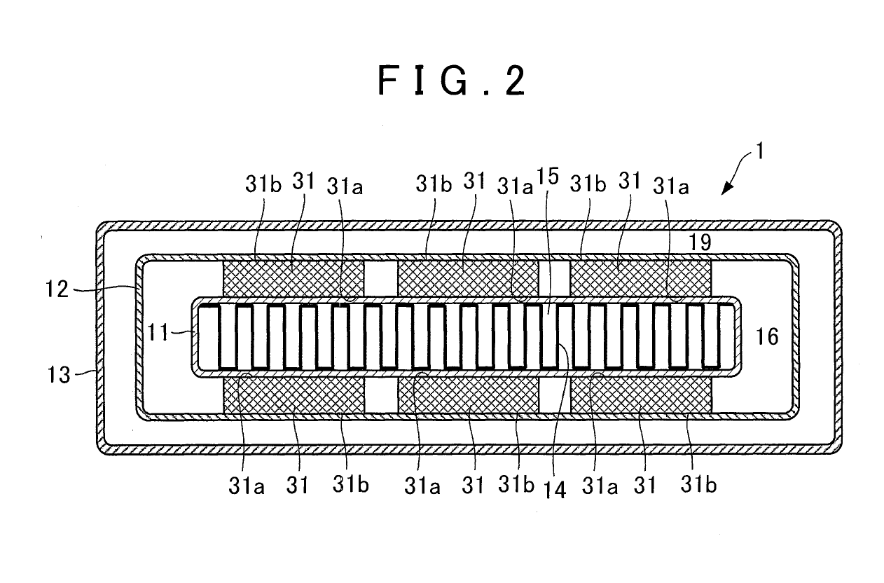

As shown in FIG. 1 and FIG. 2, the thermoelectric generator 1 according to this embodiment includes a first hollow body 11, a second hollow body 12, a third hollow body 13, a port member 21, thermoelectric devices 31, electric wires 32, a shielding member 41, radiating fins 51, and so forth. The first hollow body 11, second hollow body 12, third hollow body 13, port member 21, radiating fins 51, etc. are formed of the same metal.

The thermoelectric generator 1, which is intended for an internal combustion engine installed on an automobile, uses exhaust gas , G of the internal combustion engine as a high-temperature medium, as a high-temperature heat source, and uses coolant W of the internal combustion engine as a low-temperature medium, as a low-temperature heat source.

The first hollow body 11 has a generally rectangular shape in transverse cross-section. A heat-absorbing fin 14 is provided within the first hollow body 11. The heat-absorbing fin 14 is formed of the same metal as, the first hollow body 11. The interior cavity of the first hollow body 11 provides a high-temperature medium passage 15 through which the exhaust gas G delivered from the internal combustion engine can flow. The exhaust gas flow G is diverted from an exhaust system of the internal combustion engine.

The second hollow body 12 has a generally rectangular shape in transverse cross-section, and surrounds the first hollow body 11 in a circumferential direction. The second hollow body 12 has end walls 12a, 12b formed at one end portion and the other end portion thereof. Each of the end walls 12a, 12b extends from the entire perimeter of a peripheral portion of the second hollow body 12 so as to abut on the entire perimeter of an outer portion of the first hollow body 11.

Inner peripheral portions of the end walls 12a, 12b are air-tightly fixed by welding to the outer portion of the first hollow body 11. Thus, the outer portion of the first hollow body 11, inner portion of the second hollow body 12, and the end walls 12a, 12b cooperate to form an enclosed space 16.

The third hollow body 13 has a generally rectangular shape in transverse cross-section, and surrounds the second hollow body 12 in a circumferential direction.

The third hollow body 13 has end walls 13a, 13b formed at one end portion and the other end portion thereof Each of the end walls 13a, 13b extends from the entire perimeter of a′ peripheral portion of the third hollow body 13 so as to abut on the entire perimeter of an outer portion of the second hollow body 12.

Inner peripheral portions of the end walls 13a, 13b are air-tightly fixed by welding to the outer portion of the second hollow body 12. A coolant feed pipe 17 is connected by welding to one end portion of the third hollow body 13, and a coolant delivery pipe 18 is connected by welding to the other end portion of the third hollow body 13. The coolant feed pipe 17 and the coolant delivery pipe 18 are formed of the same metal as the first hollow body 11.

The outer portion of the second hollow body 12, the inner portion of the third hollow body 13, and the end walls 13a, 13b cooperate to form a low-temperature medium passage 19 through which the coolant W can flow. The coolant feed pipe 17 serves to feed the coolant W to the low-temperature medium passage 19. The coolant delivery pipe 18 serves to deliver the coolant W. The flow of the coolant W is diverted from a coolant circulation system of the internal combustion engine.

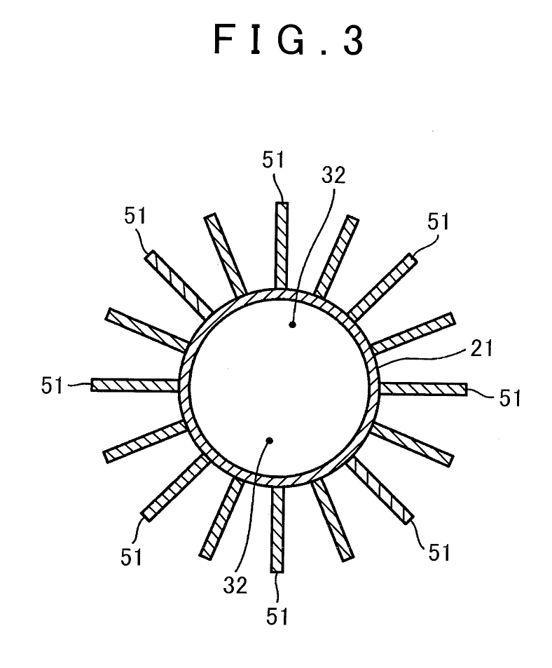

The port member 21 has a circular cross-sectional shape as shown in FIG. 3. The port member 21 is connected at one end portion to the other end portion of the second hollow body 12 by welding, so that the internal cavity of the port member 21 communicates with the enclosed space 16. The port member 21 has an opening 21 a in the other end portion. Further, the port member 21 extends away from the second hollow body 12, and extends along the low-temperature medium passage 19, such that the opening 21a is spaced apart from the high-temperature medium passage 15.

The thermoelectric devices 31 consist of Peltier devices, each of which is a known device that develops electromotive force, owing to the Seebeck effect that depends on a temperature difference between a high-temperature-side end face 31a and a low-temperature-side end face 31b.

A plurality of thermoelectric devices 31 are placed in the enclosed space 16, such that the high-temperature-side end face 31a of each of the devices 31 is in contact with the outer portion of the first hollow body 11, and the low-temperature-side end face 31 b is in contact with the inner surface of the second hollow body 12.

The electric wires 32 are inserted through the port member 21, and one end portion of each wire 32 is connected to the thermoelectric devices 31, while the other end portion is pulled out to the outside of the port member 21 through the opening 21a.

The shielding member 41 is formed of a highly-elastic resin material, such as silicone rubber, or synthetic rubber. The shielding member 41 is fitted in the opening 21a of the port member 21, and its outer circumferential portion adheres tightly to an inner circumferential wall of the opening 21a so as to seal the enclosed space 16 with respect to the outside closely. Also, the electric wires 32 pass through the shielding member 41 such that airtightness of the enclosed space 16 is maintained by the shielding member 41.

A plurality of radiating fins 51 are fixed by welding to an outer portion of the other end portion of the port member 21. The plurality of radiating fins 51 are arranged in a radial fashion with respect to the axis of the port member 21, as viewed in the axial direction of the other end portion of the port member 21. The position of the radiating fins 51 in the axial direction, of the port member 21 corresponds to the position of the shielding member 41 in the axial direction of the port member 21. Specifically, the radiating fins 51 is provided at a position close to or overlapping with the shielding member 41 in the axial direction of the port member 21.

The radiating fins 51 serve to release heat transferred from the exhaust gas G to the port member 21 via various routs, to the exterior, and cool the shielding member 41. The radiating fins 51 may be formed integrally with the port member 21.

Further, the enclosed space 16 in which the thermoelectric devices 31 are placed is kept in a low-oxygen condition. The enclosed space 16 may be brought into the low-oxygen condition by various methods, for example, by reducing the pressure in the enclosed space 16 and making the enclosed space 16 below atmospheric pressure and close to a vacuum, or by filling the enclosed space 16 with inert gas, such as argon, so as to remove the air.

Next, the operation of the thermoelectric generator 1 according to this embodiment will be described.

In the thermoelectric generator 1, the exhaust gas G delivered from the internal combustion engine flows through the high-temperature medium passage 15 inside the first hollow body 11, so that heat of the exhaust gas G is transmitted to the high-temperature-side end faces 31a of the thermoelectric devices 31 via the first hollow body 11, and the temperature of the end faces 31a is elevated.

Also, in the thermoelectric generator 1, the coolant W that diverges from the coolant circulation system of the internal combustion engine flows through the low-temperature medium passage 19 between the outer portion of the second hollow body 12 and the inner portion of the third hollow body 13, so that heat transferred from the low-temperature-side end faces 31b of the thermoelectric devices 31 is released to the coolant W via the second hollow body 12, and the temperature of the end faces 31b is reduced.

When the temperature of the high-temperature-side end faces 31a is elevated, and the temperature of the low-temperature-side end faces 31b is reduced, the thermoelectric generator 1 develops electromotive force, owing to the Seebeck effect that depends on a temperature difference between the high-temperature-side end faces 31a and the low-temperature-side end faces 31b. Then, electric power generated by the thermoelectric devices 31 is fed into a battery, or the like, installed on the automobile, via the electric wires 32.

In the thermoelectric generator 1, the port member 21 extends away from the second hollow body 12, and the opening 21a of the port member 21 is spaced apart from the high-temperature medium passage 15; therefore, the quantity of heat the shielding member 41 receives from the exhaust gas G can be reduced.

Also, in the thermoelectric generator 1, the port member 21 extends along the low-temperature medium passage 19; therefore, a temperature rise of the shielding member 41 can be curbed by the coolant W that flows through the low-temperature medium passage 19.

In the thermoelectric generator 1, the plurality of radiating fins 51 are fixed in a radial fashion as viewed in the axial direction, to the other end portion of the port member 21. Further, the position of the radiating fins 51 in the axial direction of the port member 21 corresponds to the position of the shielding member 41 in the axial direction of the port member 21.

Namely, the plurality of radiating fins 51 release heat transferred from the exhaust gas G to the port member 21 via various routes, to the outside of the thermoelectric generator 1, so as to cool the shielding member 41; therefore, the shielding member 41 is less likely or unlikely to deteriorate due to exhaust gas G as a high-temperature medium. In addition, the flow of air (or wind) hits against the radiating fins 51 during running of the automobile; therefore, the heat release efficiency is improved.

In the thermoelectric generator 1, the quantity of heat the shielding member 41 receives from the exhaust gas G is reduced, and a temperature rise of the shielding member 41 is curbed by the cooling water W, while heat is released to the outside via the radiating fins 51, and the enclosed space 16 is held in a low-oxygen condition;

therefore, the shielding member 41 is less likely or unlikely to deteriorate due to the exhaust gas G. Accordingly, the thermoelectric devices 31 are prevented from being exposed to the high-temperature atmosphere, and high-temperature oxidation of the thermoelectric devices 31 can be effectively prevented.

It is to be understood that the technical scope of the thermoelectric generator according to the invention is not limited to the above-described embodiment, but may include various changes of each constituent element described in the appended claims, without departing from the scope of the invention.

As described above, the thermoelectric generator according to the invention yields effects of curbing deterioration of the shielding member caused by exhaust gas, and preventing high-temperature oxidation of the thermoelectric devices. Thus, the thermoelectric generator of the invention is usefully employed in various types of internal combustion engines.

1. A thermoelectric generator comprising:
a structure that defines an enclosed space between a high-temperature medium and a low-temperature medium, the enclosed space being in a low-oxygen condition;
a thermoelectric device placed in the enclosed space;
a hollow port member having one end portion to which the structure is connected such that the hollow port member communicates with the enclosed space, the hollow port member having an opening in an other end portion of the hollow port member;
an electric wire inserted through the hollow port member, the electric wire having one end portion connected to the thermoelectric device, and the other end portion that is pulled out to an outside of the hollow port member through the opening;
a shielding member fitted in the hollow port member, the electric wire passing through the shielding member, the shielding member being configured to seal the enclosed space and the hollow port member to the outside, and the shielding member being formed of an elastic resin material; and
a cooling unit configured to cool the shielding member.

2. (canceled)

3. The thermoelectric generator according to claim 1, wherein:
the hollow port member extends away from the structure; and
the shielding member is fitted in the opening of the hollow port member.

4. The thermoelectric generator according to claim 1, wherein:
the cooling unit comprises a radiating fin; and
the radiating fin is provided on an outer portion of the hollow port member.

5. The thermoelectric generator according to claim 4, wherein the radiating fin is provided at a position close to or overlapping with the shielding member in an axial direction of the hollow port member.

6. The thermoelectric generator according to claim 1, wherein:
the structure has a low-temperature medium flow passage; and
the shielding member is located close to the low-temperature medium flow passage.

7. The thermoelectric generator according to claim 1, wherein a pressure in the enclosed space is reduced.

8. The thermoelectric generator according to claim 7, wherein the pressure in the enclosed space is below atmospheric pressure.

9. The thermoelectric generator according to claim 1, wherein the enclosed space is filled with inert gas.
